(19) United States
(12) Patent Application Publication
(10) Pub. No.: US 2013/0087856 A1
(43) Pub. Date: Apr. 11, 2013

(54) Effective Work Function Modulation by Metal Thickness and Nitrogen Ratio for a Last Approach CMOS Gate

(71) Applicants: Claude Ortolland, Peekskill, NY (US); Unoh Kwon, Fishkill, NY (US); Kota V.R.M. Murali, Bangalore (IN); Edward J. Nowak, Essex Junction, VT (US); Rajan Kumar Pandey, Bangalore (IN)

(72) Inventors: Claude Ortolland, Peekskill, NY (US); Unoh Kwon, Fishkill, NY (US); Kota V.R.M. Murali, Bangalore (IN); Edward J. Nowak, Essex Junction, VT (US); Rajan Kumar Pandey, Bangalore (IN)

(73) Assignee: International Business Machines Corporation, Armonk, NY (US)

(21) Appl. No.: 13/253,430

(22) Filed: Oct. 5, 2011

(51) Int. Cl. H01L 27/092; H01L 21/8238

(52) U.S. Cl. 257/365; 257/369; 438/199; 257/E27.062; 257/E21.632

(57) ABSTRACT

A CMOS structure is formed on a semiconductor substrate that includes first and second regions having an nFET and a pFET respectively formed thereon. Each nFET and pFET device is provided with a gate, a source and drain, and a channel formed on the substrate. A high permittivity dielectric layer formed on top of the channel is superimposed to the permittivity dielectric layer. The pFET gate includes a thick metal nitride alloy layer or rich metal nitride alloy or carbon metal nitride layer that provides a controlled WF. Superimposed to the permittivity dielectric layer, the nFET gate is provided with a thin metal nitride alloy layer, enabling to control the WF. A metal deposition is formed on top of the respective nitride layers. The gate last approach characterized by having a high thermal budget smaller than 500° C. used for post metal deposition, following the dopant activation anneal.

### FIELD OF THE INVENTION

The present invention relates to semiconductor devices and methods of fabricating, and more particularly, to a method for achieving a band-edge effective work function using the same metal through a CMOS gate. The present invention is applicable to planar or 3D devices by varying the thickness and nitrogen concentration of the eWF metal.

### BACKGROUND AND RELATED ART

A “work function” (WF) is generally described as the energy, usually measured in electron volts, needed to remove an electron from the Fermi level to a point immediately outside the solid surface or the energy needed to move an electron from the Fermi level into vacuum. Work function is a material property of any material, whether the material is a conductor, semiconductor, or dielectric. For a metal, the Fermi level lies within the conduction band, indicating that the band is partly filled. For an insulator, the Fermi level lies within the band gap, indicating an empty conduction band; in the case, the minimum energy to remove an electron is about the sum of half the band gap and the electron affinity. An effective work function (eWF) is defined as the work function of metal on the dielectric side of a metal-dielectric interface.

The work function of a semiconductor material can be altered by doping the semiconductor material. For example, undoped polysilicon has a work function of about 4.65 eV, whereas polysilicon doped with boron has a work function of about 5.15 eV. When used as a gate electrode, the work function of a semiconductor or conductor directly affects the threshold voltage of the transistor.

The work function is a key parameter for setting the threshold voltage (Vth) of the CMOS device, whether an n-type FET or a p-type FET. In order to obtain a good electrical control of the FET devices, the work function value should be close to the valence band of the semiconductor for a pFET and close to the conduction band of the semiconductor for an nFET, and more particularly, 5.2 eV and 4.0 eV, respectively for the pFET and nFET in the case of silicon.

Recent technologies have migrated from a gate stack made of silicon oxide (SiO₂ or SiON) for the gate dielectric, and polysilicon for the gate electrode, to a high permittivity dielectric (Hk) with SiO₂, for gate dielectric and metal layer in order to set up the right effective work function with or without polysilicon forming the gate stack.

Different approaches exist to achieve a particular CMOS device having Hk/MG used in the gate stack. The first one, known as a ‘gate first approach’, is a direct continuity of previous technologies with polysilicon or SiO₂: Hk. Metal layers are deposited, and followed by a polysilicon deposition. Then, the stack is selectively etched to obtain the gate electrode. Device junction are formed by way of different implantations followed by an activation anneal (high thermal budget >900° C.). In a second approach, known as ‘gate last approach’, a dummy gate is used as the gate electrode to enable a junction implantation and activation anneal. Further down the process, when devices are fully covered by a thick dielectric to the top of the gate, the dummy gate is removed and replaced by the final gate stack that includes the gate dielectric and the work function metal. With this approach, no high thermal budget (e.g. dopant activation anneal) is applied after the metal, avoiding drift of its WF.

Existing technologies form advanced CMOS devices effectively using additional capping (like aluminum based or Lanthanum based capping) using the same eWF metal in order to achieve the appropriate work function of the p-type and n-type devices to attain the appropriate threshold voltage. The aforementioned process is mainly employed for the ‘gate first approach’ which include a high thermal budget (activation anneal, reaching temperatures higher than 900° C.). The process is relatively complex and extremely sensitive to thermal budget used for the post gate metal depositions.

Certain solutions have been advanced that use different metal thickness, one for the n-type FET, and another for the p-type FET. For a gate first approach, a gate patterning needs to be performed using different metal thicknesses, which are difficult to achieve. Moreover, a high thermal budget (e.g. the dopant activation anneal) is applied following the metal gate deposition, which can significantly affect the eWF. Thus, the process becomes more complex to when applied to CMOS technology.

In other instances, the nitrogen stoichiometry modification of a metal nitride alloy is used to modulate the metal work function to obtain the desired threshold voltage for good device control, i.e., (1−X) atoms of metal associated with X atoms of nitrogen. If X>0.5 the metal nitride alloy is nitrogen rich, if X<0.5 the metal nitride alloy is metal rich. But playing only on nitrogen stoichiometry of a metal nitride alloy it is not sufficient to obtain the right work function needed for both, the n-type and p-type FET transistors. Specially, if it is done using the ‘gate first approach’ with a high thermal budget post-metal deposition (activation anneal), it may drift the metal work function, making it even more difficult to obtain a good threshold voltage for both the nFET and pFET devices.

Certain methods employ different metals or metal alloys for the n-type and p-type devices. Each metal (or metal alloys) is characterized by having its own work function which permits the use of one for the nFET and a different one for the pFET (e.g., TiAl for nFET and TiN for pFET) in order to achieve the appropriate eWF for both devices. However, the integration of different metals increases the complexity of the process. In order to avoid any intermixing of the different metals or impact of a metal on the others (like the eWF of the entire stack), it necessitates removing some of the metal layers on some of the devices (e.g., by leaving it on the nFET and removing it on the pFET). Therefore, it requires a good selectivity among the various metals.

Referring to FIG. 1, there is shown an exemplary planar CMOS device formed on an SOI or bulk substrate [100], preferably made with a high-k dielectric and metal ‘gate last approach’ [200]. In order to form such a device, a normal planar process flow is typically used (not described here) which includes forming a source [101] and drain [102]. A high permittivity dielectric is employed for the gate oxide and metal layer, deposited post-dopant activation anneal, and used as an eWF setting. A standard CMOS process flow is performed until the Back-End-Of-Line (BEOL) phase, generally using different interconnect metal levels.

Referring to FIG. 2, an exemplary FinFET or 3D CMOS device is shown formed on an SOI or bulk substrate [103] and made with high-k dielectric and metal gate [200]. The source [101] and drain are formed using a dummy gate electrode which is removed prior to the gate stack formation. High permittivity dielectric is preferably used for the gate oxide and metal layer, and deposited following a dopant activation anneal, used for setting the eWF.

Accordingly, there is a need for a simple process to create a CMOS device for ‘last approach’ that employs a single metal layer, that is further applicable to the nFET and pFET work function metal and capable of achieving a band-edge or close work function for both types of CMOS transistors.

### BRIEF DESCRIPTION OF THE DRAWINGS

The present invention will be understood and appreciated more fully from the following detailed description of embodiments thereof taken in conjunction with the accompanying drawings.

FIG. 1 shows a prior art planar CMOS device formed on an SOI or bulk substrate using a high-k dielectric and metal gate last approach (i.e., wherein a dopant activation anneal was previously performed).

FIG. 2 illustrates a prior art FinFET or 3D CMOS device formed on an SOI or bulk substrate using a high-k dielectric and metal gate last approach.

FIG. 3 shows results of the ab-initio atomistic simulation density functional theory illustrating a work function modulation induced by nitrogen concentration at a metal to dielectric interface.

FIG. 4 shows results illustrating a pMOS Vth reduction when the metal thickness increases and an nMOS Vth reduction when the metal thickness decreases.

FIG. 5 is a graph summarizing a thin layer of metal-rich metal nitride alloy necessary to obtain a good work function for the nFET device, and a thick layer of a nitrogen rich metal nitride alloy necessary to provide a good work function for the pFET.

FIG. 6 shows a cross section AA′ of FIGS. 1 and 2 illustrating an nMOS device formed with a thinner rich metal nitride alloy (Me-N or MeCN), while the nitrogen-rich pMOS device is formed with a thicker metal nitride alloy (Me-N or MeCN), in accordance with an embodiment of the present invention.

FIG. 7 is a cross-section view of the CMOS devices following the removal of the dummy gate applicable to the gate last approach.

FIG. 8 is a cross-section view of CMOS devices following the nitrogen-rich metal nitride alloy (or MeCN) deposition, wherein the WF metal is used for a pFET device.

FIG. 9 is a cross-section view of CMOS devices following the nitrogen-rich metal nitride alloy removal by way of standard lithography on the nFET device.

FIG. 10 is a cross-section view of a CMOS device following a second deposition of metal nitride alloy, which employs the same metal nitride alloy (or the same MeCN) as previously used, albeit metal rich in composition.

FIG. 11 is a cross-section view of CMOS devices at the end of the gate last approach process, wherein the nMOS work function is formed using a thinner metal-rich metal nitride alloy (or MeCN), and the pMOS work function is formed using the same but thicker nitrogen-rich metal nitride alloy (or MECN).

### SUMMARY

In accordance with one embodiment of the present invention, a pFET device is provided with the work function controlled by a thick metal deposition in contrast with a thin layer used to control the WF of an nFET. The thick metal for the pFET device is preferably formed by way of a deposition that extends over the nFET device, wherein by partial etch back on selected areas of the nFET region, the thin metal layer is deposited at the end of the process.

In accordance with an embodiment of the present invention, the pFET device has the work function controlled by way of nitride-metal having a high ratio of nitrogen/metal stoichiometry that is nitrogen-rich (i.e., 1−X atoms of metal for X atoms of nitrogen, wherein X>0.5: e.g., two or more nitrogen atoms for each metal atom), in contrast with the metal-rich metal nitride alloy layer used to control the WF of the nFET device (i.e., 1−X atoms of metal for X atoms of nitrogen, X<0.5: e.g. two or more metal atoms for each atom of nitrogen).

In accordance with an embodiment, the FET device is provided with a metal gate requiring an eWF of the order of 5.2 eV for a p-type FET device, ranging between approximately 4.9 to 5.0 eV and an eWF approximating 4.0 eV for an n-type FET device, and as high as about 4.2 eV. The gate last approach is used, i.e., no high thermal budget >500° C. used for a post metal deposition, the dopant activation anneal having been performed earlier, that permits keeping the metal eWF unchanged and immune to any modification as a result of a high thermal budget. The approach can be used either on planar devices or on 3D devices (like FinFET, tri-gate, and the like), on a Si bulk or an SOI substrate.

In accordance with another embodiment, metals such as Ta, Ti are nitrided in-situ, forming respectively, TiN and TaN. Carbon metal nitride (e.g., TaCN) is used as the only eWF metal applicable to both n-type and p-type CMOS devices. Furthermore, the effective Work Function (eWF) of the metal nitride alloy or carbon metal nitride alloy is controlled by two key parameters: its thickness and the nitrogen/metal stoichiometry of the metal nitride alloy (1−X atoms of metal for X atoms of nitrogen). The thin metal decreases the eWF (<3 nm) whereas a thick metal (>5 nm) increases the eWF. A metal nitride alloy or carbon metal nitride which is metal-rich (1−X atoms of metal for X atoms of nitrogen, wherein X<0.5, e.g., two or more metal atoms for each nitrogen atom) decreases the eWF, and the metal nitride alloy or carbon metal nitride which is nitrogen-rich (1−X atoms of metal for X atoms of nitrogen where X>0.5 e.g. two or more nitrogen atoms for each metal atom) increases the eWF. Consequently, a thin metal-rich metal nitride alloy or carbon metal nitride is preferably used for the n-type FET devices, whereas a thick nitrogen-rich of the same metal nitride alloy or carbon metal nitride is used for the p-type FETs.

According to an embodiment, a complementary metal-oxide-semiconductor (CMOS) structure is provided that includes a semiconductor substrate having nFET and pFET devices respectively built in a first and second region thereof. A high permittivity dielectric layer is deposited on top of the channel, and superimposed to the permittivity dielectric layer. A pFET gate is constructed using a nitrogen-rich thick metal nitride alloy layer or carbon metal nitride layer that provides a controlled WF. Superimposed to the permittivity dielectric layer, the nFET gate is formed including a metal-rich thin metal nitride alloy layer providing a controlled WF, and a metal deposition on top of the respective nitride layers. The thickness of the depositions is variable. The nitrogen ratio of the nitride-metal or carbon metal nitride alloy can be advantageously applied for WF engineering.

### DETAILED DESCRIPTION

The present disclosure relates to forming a pFET device by controlling its work function (WF) employing a thick metal nitride alloy or carbon metal nitride alloy, both of which are nitrogen rich (1−X atoms of metal for X atoms of nitrogen, wherein X>0.5, e.g., two or more nitrogen atoms for each metal atom), and forming a complementary nFET device by controlling its WF employing the same metal nitride alloy or carbon metal nitride alloy, but having a thin layer of the aforementioned metal nitride alloy and which is metal-rich (1−X atoms of metal for X atoms of nitrogen where X<0.5, e.g., two or more metal atoms for each nitrogen atom).

The pFET and nFET transistors thus constructed and method of fabrication will now be described in greater detail by referring to the following description and drawings that accompany the present application. It is noted that the drawings of the present application are provided for illustrative purposes and, as such, they are not drawn to scale.

In the following description, numerous specific details are set forth, such as particular structures, components, materials, dimensions, processing steps and techniques, in order to provide a thorough understanding of the present disclosure. However, it will be appreciated by one of ordinary skill in the art that the present disclosure may be practiced with viable alternative process options without these specific details. In other instances, well-known structures or processing steps have not been described in detail in order to avoid obscuring the various embodiments of the present invention.

FIG. 3 illustrates results obtained by applying an ab-initio atomistic simulation density functional theory showing the Work Function modulation induced by the concentration of N at a metal-to-dielectric interface. More particularly, an arbitrary gate stack comprising HfO₂ includes a high permittivity dielectric, in which TiN represents the metal nitride alloy. Further illustrated, are equal amounts of Ti and N (i.e., one atom of Ti for each atom of N) present at the interface with HfO₂ displaying a simulated eWF of about 4.512 eV. On the other hand, with a nitrogen rich interface (i.e., more N than Ti), the simulated eWF becomes 5.2 eV, a distinct improvement for the pFET threshold voltage control. Furthermore, with a metal rich interface (i.e., more Ti than N), the simulated eWF is about 4.34 eV, a significantly improvement for the nFET threshold voltage control.

In order to have a nitrogen- or metal-rich interface, a metal nitride alloy, nitrogen-rich or metal-rich will be used respectively to setup the eWF of the pFET and nFET devices.

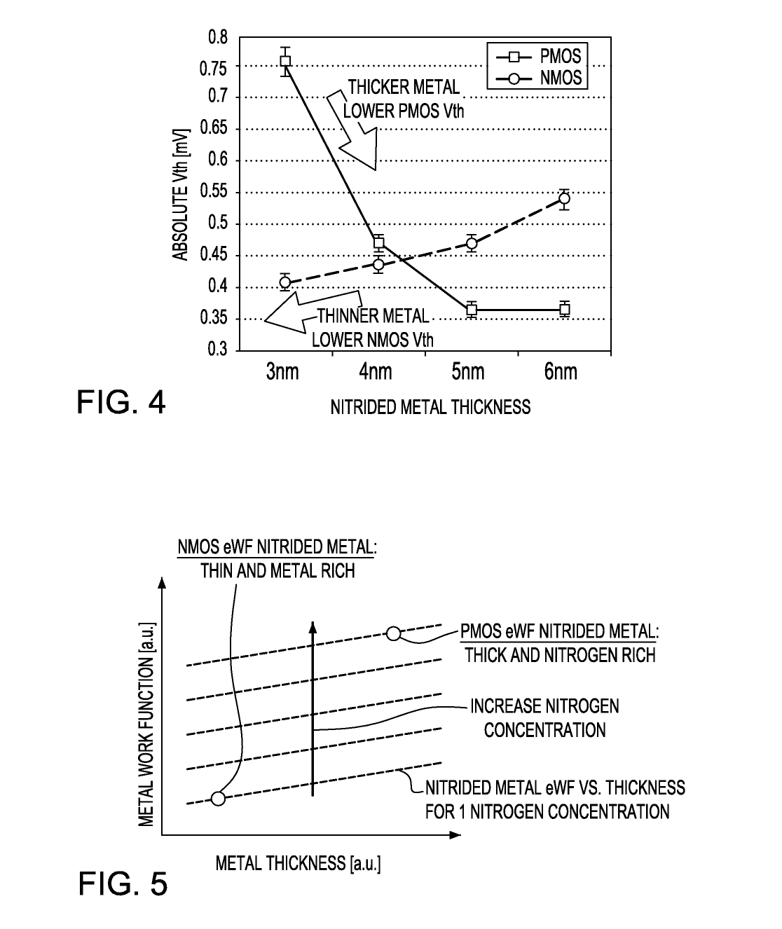

Referring to FIG. 4, there is shown a plot illustrating how the threshold voltage of the nFET and pFET varies as a function of the thickness of a metal nitride alloy. In order to ensure a good control of the device, the threshold voltage Vth may preferably range between 0.3 and 0.4V, depending on the circuit application (high performance circuit will need pFET device threshold voltage than low power circuit). An excessively high Vth (e.g. >0.45V) will induce a too low device performance. The metal nitride alloy thickness is the other main parameter used to modify the device Vth. It is clear that a thin nitride layer metal (<3 nm) is more advantageous for the nFET, whereas a thick layer, i.e., (>5 nm) is more beneficial for the pFET devices.

FIG. 3 and FIG. 4 illustrate how to easily modulate eWF using the same metal nitride alloy or carbon metal nitride alloy. The nitrogen and metal ratio and the metal thickness enable changing the eWF to setup the device threshold voltage.

Referring to FIG. 5, the results are summarized in one graph, in which a metal-rich thin metal nitride alloy is used to achieve a good WF for the nFET, and a nitrogen rich thick metal nitride alloy is used to obtain a good WF for pFET. The graph represents the effective work function of a metal nitride alloy as a function of the thickness of the metal nitride alloy and the nitrogen ratio thereby. To obtain an effective work function ideal for the nFET device the thin metal nitride alloy which is metal rich is necessary. In order to achieve an effective work function ideal for a pFET device, a thick nitrogen-rich metal nitride alloy is necessary.

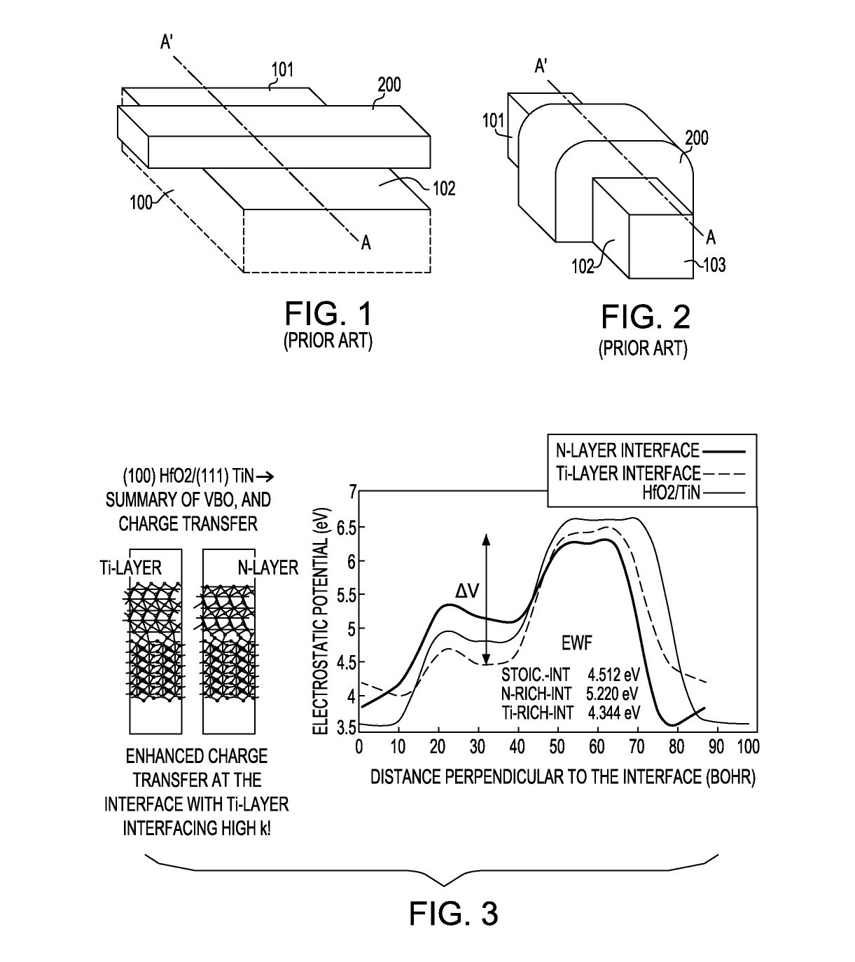

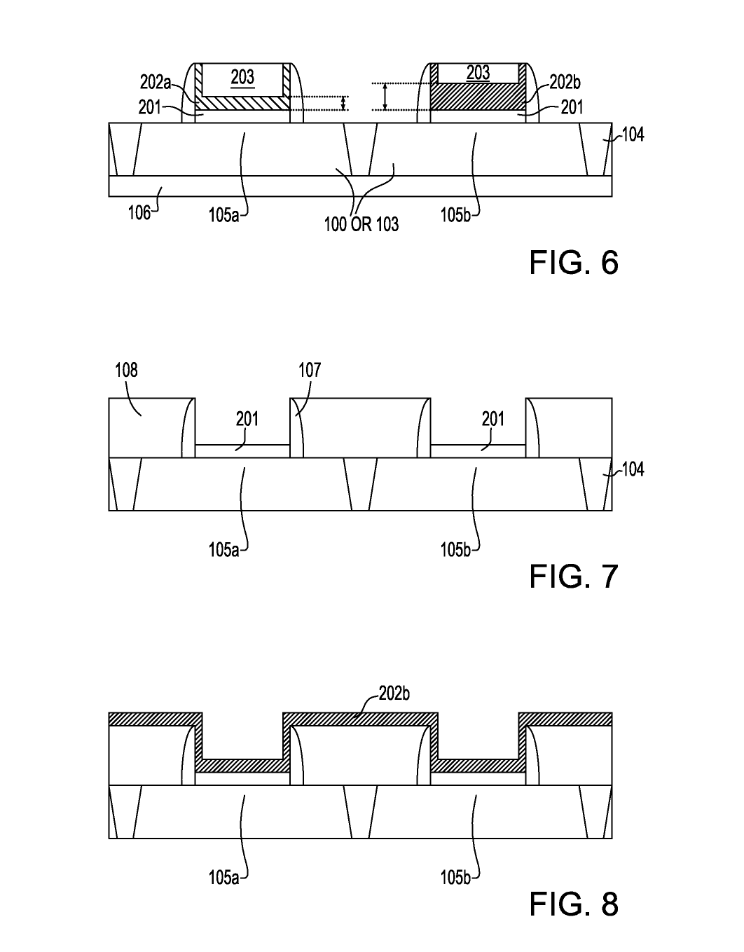

Referring to FIG. 6, there is shown a cross-section AA′ showing the planar device illustrated in FIG. 1 or a FinFET or 3D device depicted in FIG. 2 using the materials summarized in FIG. 5. Shown in FIG. 6 is a FET device formed with a metal-rich thinner metal nitride alloy or carbon metal nitride alloy, and a pFET device formed with a nitrogen-rich thicker metal nitride alloy or carbon metal nitride alloy nitrogen rich. The aforementioned two regions are employed to form the CMOS, i.e., an nFET device [105a] on the right-end side and a pFET [105b] on the left-end side. The two regions, nFET and pFET, are formed using silicon or other semiconductor material [100] or [103], which may take the form of a buried oxide (BOX) [106] in a SOI substrate, isolated by a shallow trench isolation (STI) [104]. Both devices are provided with a source, drain and gate electrode, and formed with an associated junction (not shown) into the silicon or the other semiconductor material. The gate stack is preferably provided with a height ranging from 20 to 100 nm.

The gate stack preferably includes (from bottom to top), gate dielectric [201] having a thickness approximately 1 to 2 nm, and preferably made of silicon oxide and/or a high permittivity dielectric. The work function metal nitride alloy or nitride carbon metal is selected from TiN, TaN, TaCN and the like, with a filling metal having low resistivity, e.g., Al or W. The same work function metal nitride alloy or carbon metal nitride alloy can be used for both n-type and p-type FET devices. In order to correctly set up eWF and the threshold voltage of the devices, a material rich thin metal nitride alloy or carbon metal nitride alloy is used for the nFET device (<3 nm) [202a]. The nitrogen-rich thick metal nitride alloy or carbon metal nitride alloy is used for the pFET (>5 nm) transistor [202b]. On top of it, a low resistivity conductive material [203] is deposited, such as metal that include Al or W.

Hereinafter, a description follows of a preferred process flow to obtain a metal rich thin metal nitride alloy or carbon metal nitride alloy for the WF metal of the nFET and the nitrogen rich thick metal nitride alloy or carbon metal nitride alloy for the WF metal of the pFET device, that can be obtained advantageously using different paths, of which only one will be described hereinafter.

The preferred process flow is used to form the device, regardless whether a planar, a FinFET or a 3D device, using isolation, a dummy gate, spacer(s) and ion implantation, and a high temperature activation anneal. Activation anneal is done prior the metal gate deposition in order to obtain the aforementioned gate last approach.

Referring to FIG. 7, a cross-sectional perspective view of the CMOS devices is depicted prior to the Work Function metal deposition and subsequent to the dummy gate removal for the gate last approach, (wherein the activation anneal is known to have been already performed).

At this stage, both nFET [105a] and pFET [105b] devices have been formed employing different implantation and activation anneal. The nFET and pFET regions are delimited by shallow trench isolation (STI) [104]. The respective spacers [107] and junction to form the source and drain of the devices are preferably already performed with the help of a dummy gate (not shown) to achieve a proper alignment. Then, a thick dielectric [108] is deposited and planarized, preferably using CMP (chemical mechanical polish). The dummy gate is then removed following the planarization to provide the necessary room to complete the gate stack. A gate dielectric [201] having a thickness of approximately 1 to 2 nm is also present and advantageously formed using SiO₂ and/or other high permittivity dielectrics, such as HfO₂, ZrO₂, and the like.

Following the process flow described with reference to FIG. 7, referring to the nFET [105a] and pFET [105b] regions, the metal layers are deposited using a suitable deposition technique, e.g. ALD, PECVD, PVD, and the like. The metal layer of choice is a metal nitride alloy or carbon metal nitride alloy, known to be nitrogen rich, i.e., the stoichiometry ratio between the nitrogen and the metal is greater than one (more nitrogen than metal).

Referring now to FIG. 8, a cross-sectional perspective view is illustrated of the CMOS device immediately following the application of nitrogen-rich metal nitride alloy or carbon metal nitride alloy [202b] deposition. The WF metal is subsequently used to form the p-type FET.

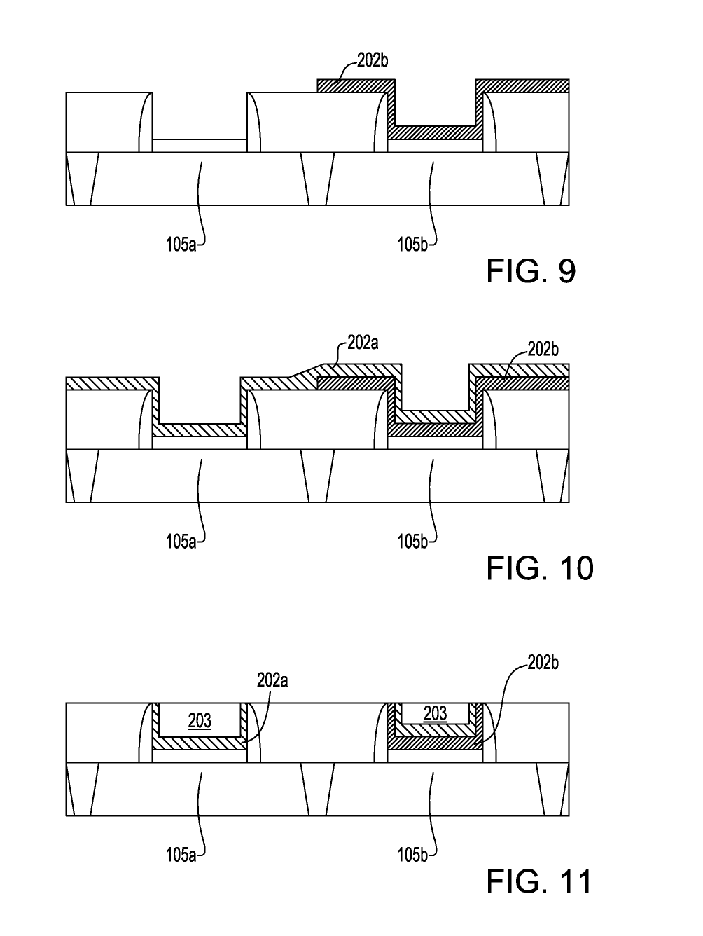

Referring to FIG. 9, a cross-sectional perspective view of the CMOS transistors following the nitrogen-rich metal nitride alloy deposition in which material has been removed from the top of the nFET device.

Still referring to FIG. 9, the nitrogen-rich, nitride-metal alloy is locally removed in the nFET devices region [105a], preferably using lithography. The photoresist deposition is followed by a second lithography with help of a mask in order to keep the resist on the pFET region [105b] and in order to protect it. The metal etch on nFET can be performed by wet chemistry or by plasma, which makes it possible to remove it completely, stopping at the gate dielectric.

The gate stack of the nFET devices illustrated in FIG. 9 shows only the gate dielectric [201] to be included. On the other hand, the gate stack of pFET devices includes, besides the gate dielectric [201], a nitrogen-rich metal nitride alloy layer [202b].

Referring to FIG. 10, a cross-sectional perspective view of the CMOS device is shown following the second deposition [202a] of the metal nitride alloy. The same metal nitride alloy or carbon metal nitride alloy are preferably used for the first deposition, such that if TiN was already deposited for the pFET device, then, TiN is preferably also to be deposited subsequently. However, instead of using a rich-metal nitride alloy nitrogen, a metal-rich composition [202a] is preferably deposited. This signifies that the stoichiometry ratio between the nitrogen atoms and metal atoms is less than one (i.e., the metal nitride alloy having more atoms of metal than nitrogen's). The same metal nitride alloy or carbon metal nitride alloy which was previously deposited is once again redeposited a second time, and used for the phase of a metal rich composition. This allows having the metal rich composition [202a] at the interface with the gate dielectric in the nFET region [105a] and having a nitrogen rich composition [202b] at the interface with the gate dielectric in the pFET region [105b].

FIG. 11 is a cross-sectional view of the CMOS device after the end of the last process step of forming the gate last approach process. The process is completed with the deposition of the filling metal [203] to reduce the gate resistivity and planarization of the devices. The final thickness of the metal nitride alloy [202b]+[202a] or carbon metal nitride alloy is higher for the pFET region [105b] compared to the nFET region [105a] where metal nitride alloy [202a] was deposited and kept once. The thick metal nitride alloy helps to set up a low threshold voltage for pFET devices where the thin metal nitride alloy helps to set up a low threshold voltage for NFET devices. An nFET WF is formed with a thinner metal nitride alloy or carbon metal nitride alloy, and metal-rich deposition [202a]. The pFET Work Function is formed employing the same material, but with a thicker metal nitride alloy (or MeCN), albeit nitrogen rich [202b].

The embodiments of the present invention are characterized by the simplicity of the process, by the absence of nFET WF metal on top of the pFET device and by the absence of a pFET WF metal on top of the nFET device. This enables generating significantly more room for the filled metal following the WF metal. It further makes it possible to obtain a low gate resistance, reduce the interfacial resistance thanks to reduction of different number of metal used which is reduced to only two, i.e., WF metal and the filled metal layers, and which also leads to have a lesser nFET/pFET boundary impact in the region where the gate is shared between both FET devices.

While the present disclosure has been particularly shown and described with respect to preferred embodiments thereof, it will be understood by those skilled in the art that the foregoing and other changes in forms and details may be made without departing from the spirit and scope of the present disclosure. It is therefore intended that the present disclosure not be limited to the exact forms and details described and illustrated, but fall within the scope of the appended claims.

1. A complementary metal-oxide-semiconductor (CMOS) structure comprising:
a. a semiconductor substrate having at least one pFET device region and at least one nFET device region located thereon, said regions having respectively nFET and pFET devices each of which having a gate, a source, a drain, and a channel;
b. said gate comprising a high permittivity dielectric layer on top of said channel;
c. said pFET gate further comprising a thick metal nitride alloy layer which is nitrogen rich, providing a controlled work function (WF), and superimposed on said permittivity dielectric layer, said nFET gate comprising a thin metal-rich metal nitride alloy layer providing said controlled WF; and
d. a gate filling metal deposition on top of said respective metal nitride alloy layers.

2. The CMOS structure of claim 1, wherein said metals have a WF that ranges from about 4.7 eV to about 5.0 ev.

3. The CMOS structure of claim 1, wherein said metal-rich metal nitride alloy is characterized by having a higher count of metal atoms than nitrogen atoms.

4. The CMOS structure of claim 3, wherein a thin, smaller than 3 nm metal-rich, nitride-metal or carbon metal nitride alloy sets an effective work function (eWF) of said nFET devices.

5. The CMOS structure of claim 1, wherein said pFET device is provided with said WF controlled by a nitrogen-rich metal nitride alloy having a high ratio of nitrogen or metal stoichiometry by way of a thick nitride metal or metal carbon nitride, setting the eWF of said pFET devices with a change in the stoichiometry.

6. The CMOS structure of claim 1, wherein a thick nitrogen rich nitride metal or carbon metal nitride alloy sets up said eWF of said pFET device.

7. The CMOS structure of claim 1, further comprising a gate last approach having a high thermal budget not exceeding 600° C. post metal nitride alloy deposition.

8. The CMOS structure of claim 1, wherein said FETs are planar or three dimension transistors including FinFETs and Tri-gate devices.

9. The CMOS structure of claim 1, wherein said pFET WF is controlled by metal nitride alloy having a high ratio of nitrogen and metal stoichiometry.

10. The CMOS structure of claim 8, wherein said nFET device WF is controlled by said metal-rich metal nitride alloy layer having a low ratio nitrogen and metal stoichiometry.

11. The CMOS structure of claim 8, wherein said pFET device is provided with a metal gate requiring an eWF of about 5.2 eV, ranging between approximately 4.9 to 5.0 eV, said nFET eWF approximating 4.0 eV, with a high of around 4.2 eV.

12. The CMOS structure of claim 8, further comprising a gate last approach characterized by having the high thermal budget smaller than 500° C. used for a post metal deposition following said dopant activation anneal to keep the metal eWF unchanged and immune to modifications.

13. The CMOS structure of claim 8, wherein said eWF is controlled by the thickness and the metal and nitrogen stoichiometry of said metal nitride alloy.

14. The CMOS structure of claim 8, wherein said thin metal less than or equal to 3 nm decreases said eWF, and wherein a thick metal greater or equal to 5 nm increases said eWF.

15. The CMOS structure of claim 8, wherein said nFET, said thin rich metal nitride alloy or said carbon metal nitride decreases said eWF, and wherein pFET said thick nitrogen-rich metal nitride alloy or carbon metal nitride increases the eWF.

16. A method of fabricating a complementary metal-oxide-semiconductor (CMOS) structure comprising:
a. forming on a semiconductor substrate at least one pair of nFET and pFET devices, each of said devices respectively having a source, a drain, a gate, and a channel;
b. depositing a high permittivity dielectric layer directly on top of each of said channels,
c. depositing on said pFET gate a thick metal nitride alloy layer superimposed on said permittivity dielectric layer, and a thin metal nitride alloy layer directly on top of nFET gate, providing a controlled WF; and
d. completing a gate stack by depositing a second metal rich layer on top of said first metal nitride alloy layer.

17. The method as recited in claim 16, wherein depositing said metal rich layer is positioned at an interface with said gate dielectric on said nFET device and having a nitrogen rich composition at the interface with said gate dielectric on said pFET device.

18. The method as recited in claim 16, wherein said gate stack of said nFET device comprises said gate dielectric and said gate stack of said pFET device comprises said gate dielectric said nitrogen rich metal nitride alloy layer.

19. The method as recited in claim 16 further comprising forming a gate last approach process using a deposition of metal filling metal to reduce gate resistivity and planarization of said devices.

20. The method as recited in claim 16, further comprises depositing said metal nitride alloy has a final thickness of the metal nitride alloy that is higher for said pFET device than the corresponding thickness of said nFET region.
